(19) United States
(12) Patent Application Publication
(10) Pub. No.: US 2014/0211175 A1
(43) Pub. Date: Jul. 31, 2014

(54) ENHANCING RESOLUTION IN LITHOGRAPHIC PROCESSES USING HIGH REFRACTIVE INDEX FLUIDS

(71) Applicant: GLOBAL FOUNDRIES INC., Grand Cayman (KY)

(72) Inventors: Lokesh Subramany, Clifton Park, NY (US); Yayi Wei, Altamont, NY (US)

(73) Assignee: GLOBALFOUNDRIES INC., Grand Cayman (KY)

(21) Appl. No.: 13/755,182

(22) Filed: Jan. 31, 2013

(51) Int. Cl. G03F 7/20

(52) U.S. Cl. CPC G03F 7/70325
USPC 355/30

(57) ABSTRACT

An approach for enhancing resolution in a lithographic process (e.g., an immersion lithographic process) is provided. Specifically, a material having a high reflexive index (e.g., water) is provided on opposite sides of an objective lens. This allows a set of light rays (high intensity) to be directed/passed from a light source, through a condenser lens, over a mask, through the material positioned on one side of the objective lens, through the objective lens, through the material on the opposite side of the objective lens, and to a wafer that is then patterned. Positioning the material on both sides of the objective lens allows for improved resolution and lithographic patterning of the wafer for both on-axis illumination and off-axis illumination techniques.

### BACKGROUND

1. Technical Field

This invention relates generally to the field of lithography and, more particularly, to approaches for enhancing resolution in lithographic processes using high refractive index fluids (e.g., in immersion lithography).

2. Related Art

Lithography is a common technique utilized in semiconductor processing. Although there are many types of lithographic processes, a common type of lithography is known as dry optical lithography whereby a wafer is irritated (e.g., via a laser) through a series of lenses and a mask. One type of laser is an argon fluoride laser (ArF laser), which is a particular type of excimer laser, that may also be referred to as an exciplex laser. With a certain wavelength, an ArF laser is a deep ultraviolet laser that is commonly used in the production of semiconductor integrated circuits. The term excimer is an abbreviation for ‘excited dimer’, while exciplex is short for ‘excited complex’. An excimer laser typically uses a mixture of a noble gas (e.g., argon, krypton, or xenon) and a halogen gas (e.g., fluorine or chlorine), which, under suitable conditions of electrical stimulation and high pressure, emits coherent stimulated radiation (laser light) in the ultraviolet range. In any lithographic process, resolution of the system is a constant variable desired to be optimized. Specifically, improved resolution yields improved patterning results.

### SUMMARY

In general, aspects of the present invention relate to an approach for enhancing resolution in a lithographic process (e.g., an immersion lithographic process). Specifically, a material having a high reflexive index (e.g., water) is provided on opposite sides of an objective lens. This allows a set of light rays (e.g., high intensity) to be directed/passed from a light source, through a condenser lens, over a mask, through the material positioned on one side of the objective lens, through the objective lens, through the material on the opposite side of the objective lens, and to a wafer that is then patterned. Positioning the material on both sides of the objective lens allows for improved resolution and lithographic patterning of the wafer for both on-axis illumination and off-axis illumination techniques.

A first aspect of the present invention provides a method for enhancing resolution in a lithographic process, comprising: providing a material having a high refractive index between a mask and an objective lens and between the objective lens and a wafer; and passing a set of light rays from a light source through a condenser lens and over the mask, wherein the set of light rays further passes through the material and the objective lens to the wafer.

A second aspect of the present invention provides a method for enhancing resolution in a lithographic process, comprising: passing a set of light rays from a light source through a condenser lens and over a mask; passing the set of light rays from the mask through a material having a high reflexive index positioned between the mask and an objective lens; passing the set of light rays through the objective lens; and passing the set of light rays through a material having a high reflexive index positioned between the objective lens and a wafer.

A third aspect of the present invention provides a lithographic system, comprising: a light source; a condenser lens positioned proximate the light source; a mask positioned proximate the condenser lens; and a material having a high refractive index positioned between the wafer and an objective lens and between the objective lens and a wafer.

### BRIEF DESCRIPTION OF THE DRAWINGS

These and other features of this invention will be more readily understood from the following detailed description of the various aspects of the invention taken in conjunction with the accompanying drawings in which:

FIG. 1 shows a dry optical lithography system.

FIG. 2 shows an immersion lithography system according to an embodiment of the present invention.

FIG. 3 shows an immersion lithography system according to an embodiment of the present invention.

FIGS. 4A-B show on-axis illumination according to an embodiment of the present invention.

FIG. 5A-B show off-axis illumination according to an embodiment of the present invention.

The drawings are not necessarily to scale. The drawings are merely representations, not intended to portray specific parameters of the invention. The drawings are intended to depict only typical embodiments of the invention, and therefore should not be considered as limiting in scope. In the drawings, like numbering represents like elements.

### DETAILED DESCRIPTION

Illustrative embodiments will now be described more fully herein with reference to the accompanying drawings, in which embodiments are shown. This disclosure may, however, be embodied in many different forms and should not be construed as limited to the embodiments set forth herein. Rather, these embodiments are provided so that this disclosure will be thorough and complete and will fully convey the scope of this disclosure to those skilled in the art. In the description, details of well-known features and techniques may be omitted to avoid unnecessarily obscuring the presented embodiments.

The terminology used herein is for the purpose of describing particular embodiments only and is not intended to be limiting of this disclosure. As used herein, the singular forms “a”, “an”, and “the” are intended to include the plural forms as well, unless the context clearly indicates otherwise. Furthermore, the use of the terms “a”, “an”, etc., do not denote a limitation of quantity, but rather denote the presence of at least one of the referenced items. The term “set” is intended to mean a quantity of at least one. It will be further understood that the terms “comprises” and/or “comprising”, or “includes” and/or “including”, when used in this specification, specify the presence of stated features, regions, integers, steps, operations, elements, and/or components, but do not preclude the presence or addition of one or more other features, regions, integers, steps, operations, elements, components, and/or groups thereof.

Reference throughout this specification to “one embodiment,” “an embodiment,” “embodiments,” “exemplary embodiments,” or similar language means that a particular feature, structure, or characteristic described in connection with the embodiment is included in at least one embodiment of the present invention. Thus, appearances of the phrases “in one embodiment,” “in an embodiment,” “in embodiments” and similar language throughout this specification may, but do not necessarily, all refer to the same embodiment.

The terms “overlying” or “atop”, “positioned on” or “positioned atop”, “underlying”, “beneath” or “below” mean that a first element, such as a first structure (e.g., a first layer) is present on a second element, such as a second structure (e.g. a second layer) wherein intervening elements, such as an interface structure (e.g. interface layer) may be present between the first element and the second element.

Immersion lithography is a photolithography resolution enhancement technique for manufacturing integrated circuits (ICs) that replaces the usual air gap between the final lens and the wafer surface with a liquid medium that has a refractive index greater than one. The resolution is increased by a factor equal to the refractive index of the liquid. Current immersion lithography tools use highly purified water for this liquid, achieving feature sizes below 45 nanometers.

As indicated above, aspects of the present invention relate to an approach for enhancing resolution in a lithographic process (e.g., an immersion lithographic process). Specifically, a material having a high reflexive index (e.g., water) is provided on opposite sides of an objective lens. This allows a set of light rays (high intensity) to be directed/passed from a light source, through a condenser lens, over a mask, through the material on one side of the objective lens, through the objective lens, through the material on the other side of the lens, and to a wafer. Positioning the material on both sides of the objective lens allows for improved resolution and lithographic patterning of the wafer for both on-axis illumination and off-axis illumination techniques.

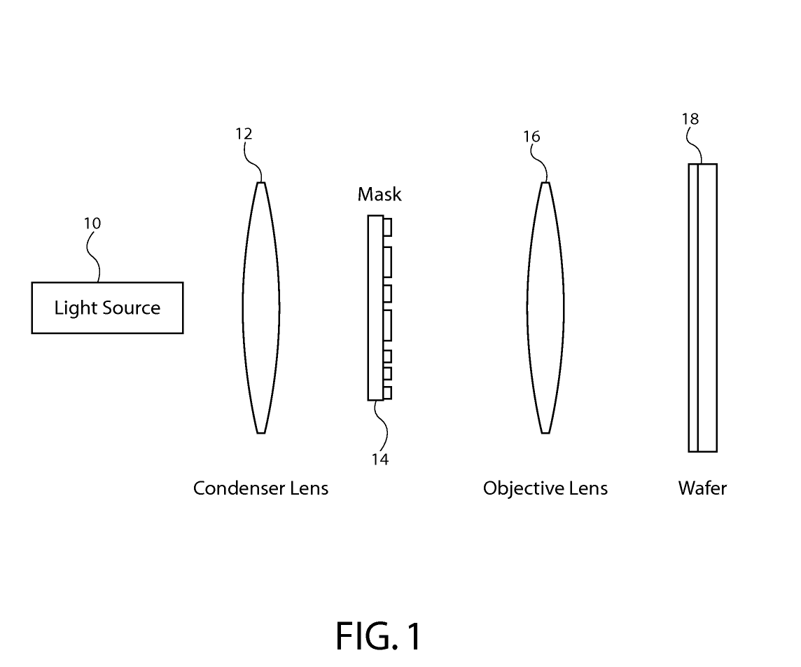

Referring now to FIG. 1, a dry optical (e.g., ArF) lithography system is shown. Specifically, FIG. 1 depicts a light source 10 that provides a set of light rays that are passed through a condenser lens 12, over a mask 14, through an objective lens 16, and onto a wafer 18. As known, the passing of such light rays over mask allows wafer to be patterned accordingly.

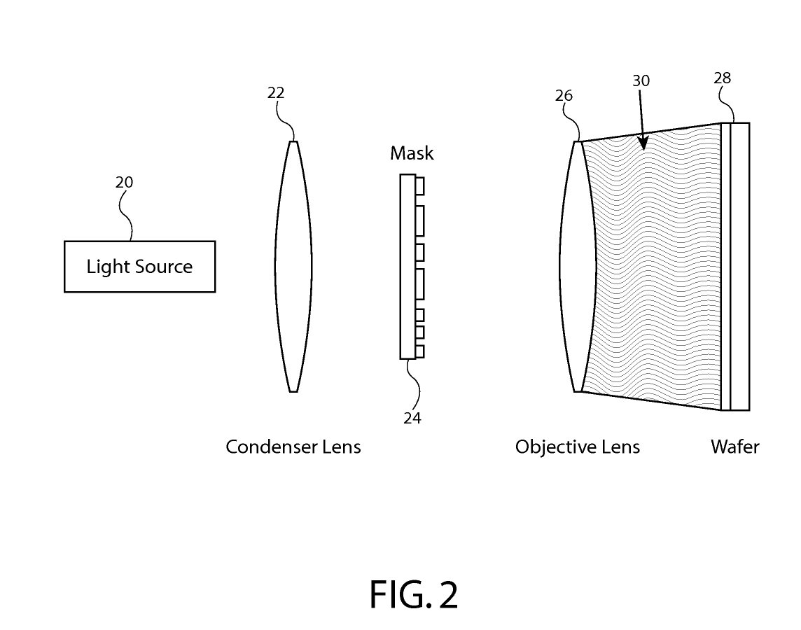

FIG. 2 depicts an immersion lithography system that generally provides improved resolution with respect to the dry optical system of FIG. 1. As depicted, the system of FIG. 2 includes a light source 20, a condenser lens 22, a mask 24, an objective lens 26, and a wafer 28. As further shown, a material 30 having a high refractive index (e.g., water or the like) is positioned between objective lens 26 and wafer 28. Light source 20 will provide a set of light rays that are passed through condenser lens 22, over mask 24, through objective lens, through material 30 and onto wafer 28. By using a high refractive index material, the image quality produced by the system is improved.

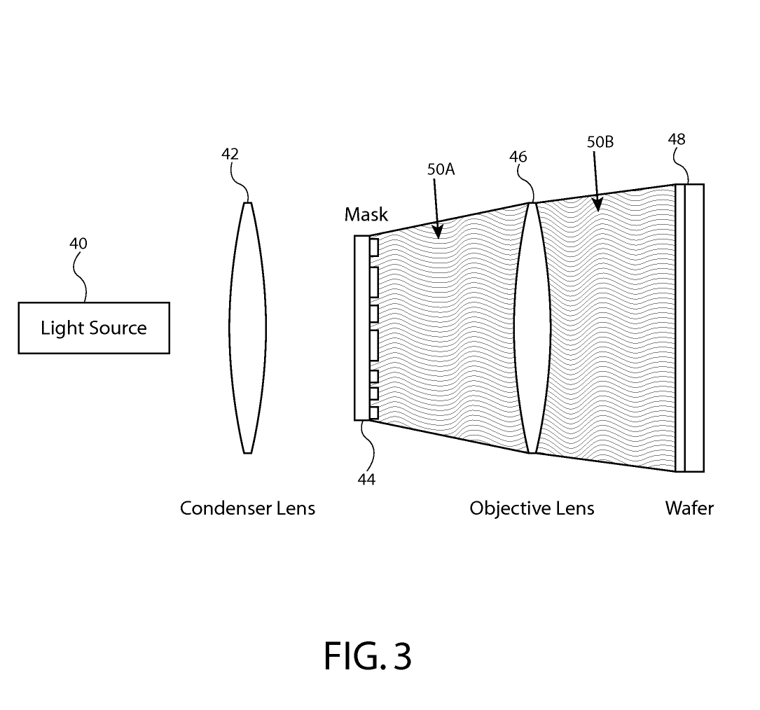

FIG. 3 depicts a more robust immersion lithography system. As shown, the system of FIG. 3 includes a light source 40 (e.g., a high intensity light source such as a laser or the like), a condenser lens 42, a mask 44, an objective lens 46, and a wafer 48. The system of FIG. 3 further includes multiple zones/areas of material 50A-B having a high refractive index. Specifically, such material 50A-B is provided on opposing sides of objective lens 46. This allows an ever greater improvement to the image quality. As such, a set of light rays emitted from light source 40 will be passed/directed through condenser lens 42, over mask 44, through material 50A, through objective lens 46, through material 50B, and onto wafer 48, which will be patterned accordingly.

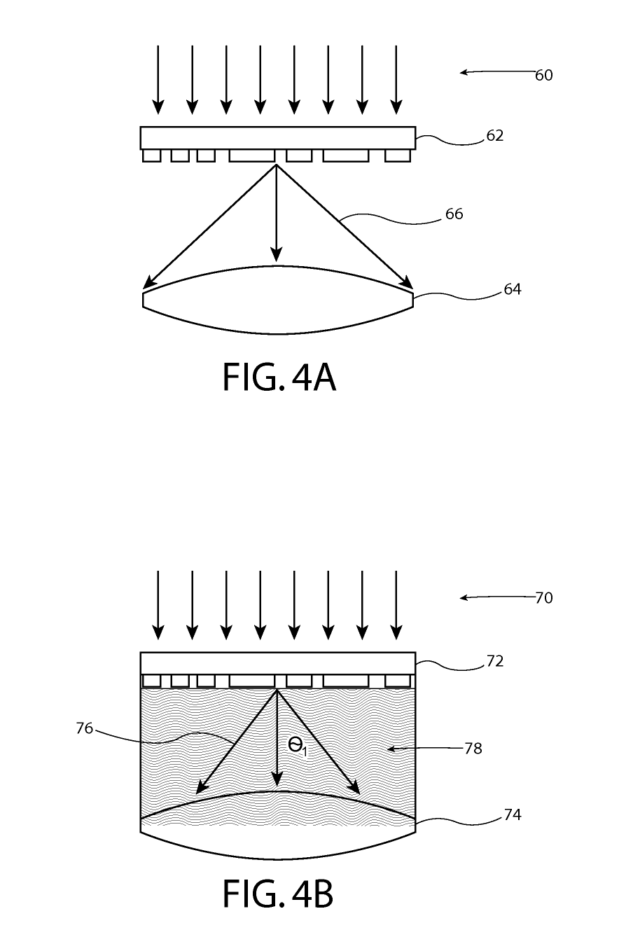

FIGS. 4A-B and 5A-B demonstrate the advantages that the system of FIG. 3 provides versus the systems of FIGS. 1-2. As shown first in FIG. 4A, when a high refractive index material is not provided between mask 62 and objective lens 64 (e.g., such as shown in FIGS. 1-2), a set of light rays 60 will provide dispersion pattern 66 through objective lens 64. That is, given a pitch of P on the mask, the arc sine of the angle between the extreme rays is λ/P·Sin θ₀=λ/P.

Conversely, as shown in FIG. 4B, when material 78 is provided between mask 72 and objective lens 74 (such as shown in FIG. 3), a set of light rays 70 will provide a more focused dispersion pattern 76 through objective lens 74. On filling the space between the make and the first lens with a high refractive index material, the arc sine of the angle between the extreme rays is reduced to λ/nP·Sin θ₁=λ/nP, where n is the refractive index of the material. Doing so allows the system to capture higher orders of diffraction that would otherwise have been diffracted away from the lens surface, thus improving the image quality. By decreasing the angle between the 0^{th} and the 1^{st} order of diffraction, the system also achieves a greater depth of focus

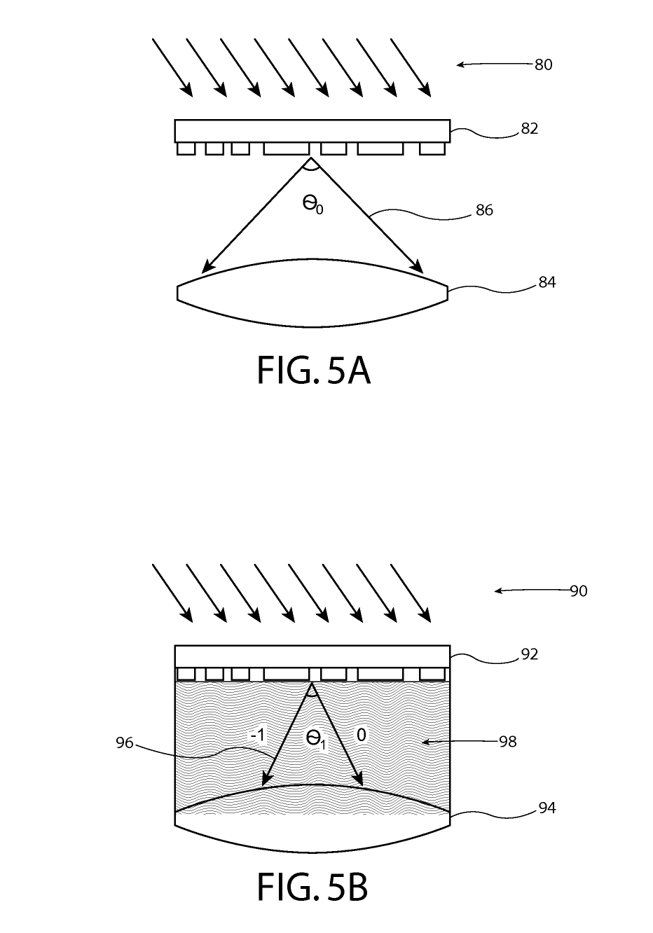

FIGS. 5A-B show similar concepts for off-angle illumination. Specifically, FIG. 5A shows an example of when a high refractive index material is not provided between mask 82 and objective lens 82 (e.g., such as shown in FIGS. 1-2, and 4A), a set of light rays 80 will provide dispersion pattern 86 through objective lens 84. That is, given a pitch of P on the mask, the arc sine of the angle between the extreme rays is λ/P·Sin θ₀=λ/P.

Conversely, as shown in FIG. 5B, when material 98 is provided between mask 92 and objective lens 94 (such as shown in FIG. 3), a set of light rays 90 will provide a more focused dispersion pattern 96 (e.g., having angle θ₁) through objective lens 94. On filling the space between the make and the first lens with a high refractive index material, the arc sine of the angle between the extreme rays is reduced to λ/nP˜Sin θ₁=λ/nP, where n is the refractive index of the material. Doing so allows the system to capture higher orders of diffraction (depending on the size of the lens) which would otherwise have been diffracted away from the lens surface, thus improving the image quality. By decreasing the angle between the 0^{th} and the 1^{st} order of diffraction, the system also achieves a greater depth of focus.

In various embodiments, design tools can be provided and configured to create the data sets used to pattern the semiconductor layers as described herein. For example, data sets can be created to generate photomasks used during lithography operations to pattern the layers for structures as described herein. Such design tools can include a collection of one or more modules and can also include hardware, software, or a combination thereof. Thus, for example, a tool can be a collection of one or more software modules, hardware modules, software/hardware modules, or any combination or permutation thereof. As another example, a tool can be a computing device or other appliance on which software runs or in which hardware is implemented. As used herein, a module might be implemented utilizing any form of hardware, software, or a combination thereof. For example, one or more processors, controllers, application-specific integrated circuits (ASIC), programmable logic arrays (PLA)s, logical components, software routines, or other mechanisms might be implemented to make up a module. In implementation, the various modules described herein might be implemented as discrete modules or the functions and features described can be shared in part or in total among one or more modules. In other words, as would be apparent to one of ordinary skill in the art after reading this description, the various features and functionality described herein may be implemented in any given application and can be implemented in one or more separate or shared modules in various combinations and permutations. Even though various features or elements of functionality may be individually described or claimed as separate modules, one of ordinary skill in the art will understand that these features and functionality can be shared among one or more common software and hardware elements, and such description shall not require or imply that separate hardware or software components are used to implement such features or functionality.

While the invention has been particularly shown and described in conjunction with exemplary embodiments, it will be appreciated that variations and modifications will occur to those skilled in the art. For example, although the illustrative embodiments are described herein as a series of acts or events, it will be appreciated that the present invention is not limited by the illustrated ordering of such acts or events unless specifically stated. Some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the formation and/or processing of structures illustrated and described herein as well as in association with other structures not illustrated. Therefore, it is to be understood that the appended claims are intended to cover all such modifications and changes that fall within the true spirit of the invention.

What is claimed is:

1. A method for enhancing resolution in a lithographic process, comprising:
providing a material having a high refractive index between a mask and an objective lens and between the objective lens and a wafer; and
passing a set of light rays from a light source through a condenser lens and over the mask, wherein the set of light rays further passes through the material and the objective lens to the wafer.

2. The method of claim 1, the lithographic process comprising immersion lithography.

3. The method of claim 1, the material comprising water.

4. The method of claim 1, the light source comprising a high intensity light source.

5. The method of claim 1, the condenser lens being positioned proximate a first side of the mask, and the objective lens being positioned proximate a second side of the mask.

6. The method of claim 1, further comprising patterning the wafer using the mask and the set of light rays.

7. The method of claim 1, the set of light rays providing on-axis illumination of the mask.

8. The method of claim 1, the set of light rays providing off-axis illumination of the mask.

9. A method for enhancing resolution in a lithographic process, comprising:
passing a set of light rays from a light source through a condenser lens and over a mask;
passing the set of light rays from the mask through a material having a high reflexive index positioned between the mask and an objective lens;
passing the set of light rays through the objective lens; and
passing the set of light rays through a material having a high reflexive index positioned between the objective lens and a wafer.

10. The method of claim 9, further comprising patterning the wafer using the set of light rays and the mask.

11. The method of claim 9, the material positioned between the mask and the objective lens and the material positioned between the objective lens and the wafer being the same material.

12. The method of claim 9, the material comprising water.

13. The method of claim 9, the set of light rays providing on-axis illumination of the mask.

14. The method of claim 9, the set of light rays providing off-axis illumination of the mask.

15. A lithographic system, comprising:
a light source;
a condenser lens positioned proximate the light source;
a mask positioned proximate the condenser lens; and
a material having a high refractive index positioned between the wafer and an objective lens and between the objective lens and a wafer.

16. The lithographic system of claim 15, the material comprising water.

17. The lithographic system of claim 15, the light source providing a set of light rays that are passed through the condenser lens, over the mask, through the objective lens, and to the wafer through the material.

18. The lithographic system of claim 17, the set of light rays patterning the wafer using the mask and the material.

19. The lithographic system of claim 15, the condenser lens being position proximate a first side of the mask, and the objective lens being position proximate a second side of the mask.

20. The lithographic system of claim 15, the lithographic system comprising an immersion lithographic system.
